(19) United States
(12) Patent Application Publication
(10) Pub. No.: US 2024/0099047 A1
(43) Pub. Date: Mar. 21, 2024

(54) DISPLAY PANEL

(71) Applicant: TCL TECHNOLOGY GROUP CORPORATION, Huizhou, Guangdong (CN)

(72) Inventor: Wenjun HOU, Huizhou, Guangdong (CN)

(21) Appl. No.: 18/263,180

(22) PCT Filed: Dec. 31, 2021
(86) PCT No.: PCT/CN2021/143934

§ 371 Date: Jul. 27, 2023

(30) Foreign Application Priority Data
Apr. 27, 2021 (CN) 202110457262.0

(51) Int. Cl. H10K 50/13; C09K 11/56; C09K 11/70; C09K 11/88; H10K 50/85

(52) U.S. Cl. CPC H10K 50/131; C09K 11/565; C09K 11/70; C09K 11/883; H10K 50/85; H10K 50/16

(57) ABSTRACT

Disclosed in embodiments of the present application is a display panel. The display panel comprises a light-emitting structure. The light-emitting structure comprises a first light-emitting unit, a second light-emitting unit, and a third light-emitting unit that are sequentially stacked, and are independently selected from a red light-emitting unit, a green light-emitting unit, and a blue light-emitting unit, respectively. A light conversion layer of the light-emitting structure is provided on the side of the green light-emitting unit and/or blue light-emitting unit close to a light exit surface of the light-emitting structure, and the light conversion layer is doped with red photoluminescent particles.

This application claims priority to Chinese Patent Application No. 202110457262.0, filed on Apr. 27, 2021, entitled “DISPLAY PANEL”, which is incorporated herein by reference in its entirety.

### TECHNICAL FIELD

The present application relates to a field of display technology, and more particularly, to a display panel.

### BACKGROUND

With rapid development of light-emitting diode technology and gradual improvement of light efficiency of the light-emitting diodes, applications of the light-emitting diodes are more and more extensive. Currently, white light-emitting diode devices are designed to emit white lights by mixing materials of red, green, and blue color in different proportions. The materials of red, green, and blue color can be processed into a film by solution processing, spin coating or ink-jet printing. Then the film can be integrated with the light-emitting diode device to function as an effective exciton radiation combination center.

The white light-emitting diode devices require injection of electrons and holes in operation, and a simplest structure of the white light-emitting diode device includes a cathode, an electron transport layer, a light-emitting layer, a hole transport layer, and an anode. In the white light-emitting diode device, the light-emitting layer is disposed between the electron transport layer and the hole transport layer. When a forward bias voltage is applied to both ends of the light-emitting diode device, electrons and holes enter the light-emitting layer through the electron transport layer and the hole transport layer, respectively, and the electrons and holes are combined to emit lights in the light-emitting layer.

However, the white light-emitting diode currently has a problem of low color rendering index, as such, the performance on color reproduction is poor. Thus, there is a need for a white light-emitting diode device having a high color rendering index.

### SUMMARY OF THE DISCLOSURE

### Technical Problem

Embodiments of the present application provide a display panel to solve a problem of a low color rendering index of a white-light display panel.

### TECHNICAL SOLUTIONS OF THE DISCLOSURE

### Summary of the Technical Solutions

An embodiment of the present application provides a display panel including:
a first electrode layer;
a light-emitting structure disposed on the first electrode layer, wherein the light-emitting structure includes a first light-emitting unit, a second light-emitting unit, and a third light-emitting unit; the first light-emitting unit, the second light-emitting unit, and the third light-emitting unit are independently selected from a red light-emitting unit, a green light-emitting unit, and a blue light-emitting unit, respectively; and the first light-emitting unit, the second light-emitting unit, and the third light-emitting unit emit lights of different colors respectively; wherein the light-emitting structure is provided with a light-converting layer, the light-converting layer is disposed on a side of the green light-emitting unit and/or the blue light-emitting unit close to a light-emitting surface of the light-emitting structure, and the light-converting layer is doped with red photoluminescence particles; and
a second electrode layer disposed on a side of the light-emitting structure away from the first electrode layer.

In some embodiments of the present application, the red photoluminescence particles are configured to receive lights emitted by the green light-emitting unit and/or the blue light-emitting unit and to emit red light, and the light-emitting structure emits white lights.

In some embodiments of the present application, the red photoluminescence particles are selected from of CdSe-based quantum dot materials, CdZnSe-based quantum dot materials, InP-based quantum dot materials, and ZnSe-based quantum dot materials.

In some embodiments of the present application, a doping concentration of the red photoluminescence particles in the light-converting layer ranges from 10% to 35%.

In some embodiments of the present application, the first light-emitting unit includes a first light-emitting layer, a first electron transport layer, and a first hole transport layer; and the light-converting layer, the first hole transport layer, the first light-emitting layer, and the first electron transport layer are stacked sequentially on the first electrode layer.

In some embodiments of the present application, a material of the light-converting layer is selected from poly(3,4-ethylenedioxythiophene): polystyrene sulfonate, polyaniline, and polythiophene.

In some embodiments of the present application, the first light-emitting unit includes a first hole injection layer, a first light-emitting layer, and a first electron transport layer; and the first hole injection layer, the light-converting layer, the first light-emitting layer, and the first electron transport layer are stacked sequentially on the first electrode layer.

In some embodiments of the present application, a material of the light-converting layer is selected from poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, and 4,4′-bis(9-carbazol)biphenyl.

In some embodiments of the present application, the first light-emitting unit includes a first hole injection layer, a first hole transport layer, and a first light-emitting layer; and the first hole injection layer, the first hole transport layer, the first light-emitting layer, and the light-converting layer are stacked sequentially on the first electrode layer.

In some embodiments of the present application, a material of the light-converting layer is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1.

In some embodiments of the present application, the light-converting layer is disposed between the first light-emitting unit and the second light-emitting unit, or between the second light-emitting unit and the third light-emitting unit. Alternatively, in some embodiments of the present application, a material of the light-converting layer is selected from indium tin oxide, indium zinc oxide, zinc aluminum oxide, indium gallium zinc oxide, zinc oxide, and zinc manganese oxide.

In some embodiments of the present application, the second light-emitting unit includes a second hole injection layer, a second hole transport layer, a second light-emitting layer, and a second electron transport layer stacked sequentially; wherein the third light-emitting unit includes a third hole injection layer, a third hole transport layer, a third light-emitting layer, and a third electron transport layer stacked sequentially; wherein the display panel further includes a first transparent conductive layer disposed between the first light-emitting unit and the second light-emitting unit and/or a second transparent conductive layer disposed between the second light-emitting unit and the third light-emitting unit.

In some embodiments of the present application, a material of each of the first light-emitting layer, the second light-emitting layer, and the third light-emitting layer is a core-shell structure, and a shell layer of the core-shell structure covers a core layer of the core-shell structure; wherein a material of the core layer includes at least one of CdSe, CdZnSe, InP, and ZnSe, and a material of the shell layer includes one or a combination of CdS and ZnS.

In some embodiments of the present application, the materials of the first transparent conductive layer and the second transparent electrode layer are selected from indium tin oxide, indium zinc oxide, zinc aluminum oxide, indium gallium zinc oxide, zinc oxide, and zinc manganese oxide.

In some embodiments of the present application, the first transparent conductive layer and the second transparent electrode layer each have a thickness ranging from 50 nm to 1000 nm.

In some embodiments of the present application, a material of each of the second electron transport layer and the third electron transport layer is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, and n1+n2+n3=1.

In some embodiments of the present application, the materials of the second hole transport layer and the third hole transport layer each include one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, and 4,4′-bis(9-carbazol)biphenyl.

In some embodiments of the present application, the materials of the second hole injection layer and the third hole injection layer are selected from poly(3,4-ethylenedioxythiophene): polystyrene sulfonate, polyaniline, and polythiophene.

In some embodiments of the present application, the second hole injection layer and the third hole injection layer each have a thickness ranging from 15 nm to 50 nm.

### BENEFICIAL EFFECT OF THE DISCLOSURE

### Beneficial Effect

An embodiment of the present application discloses a display panel. The display panel includes a first electrode layer, a light-emitting structure, and a second electrode layer. The light-emitting structure is disposed on the first electrode, and includes a first light-emitting unit, a second light-emitting unit, and a third light-emitting unit stacked sequentially. The first light-emitting unit, the second light-emitting unit, and the third light-emitting unit are independently selected from a red light-emitting unit, a green light-emitting unit, and a blue light-emitting unit, respectively. The first light-emitting unit, the second light-emitting unit, and the third light-emitting unit emit lights of different colors. The light-emitting structure is provided with a light-converting layer, the light-converting layer is doped with red light-emitting particles, and the light-converting layer is provided on a side of the green light-emitting unit and/or the blue light-emitting unit close to a light-emitting surface of the light-emitting structure. The light-emitting structure emits white lights. The second electrode layer is disposed on a side of the light-emitting structure away from the first electrode layer. In the present application, by providing the light-converting layer in the light-emitting structure, the color rendering index of the white-light display panel is improved, and the performance of the white-light display panel is further improved.

### BRIEF DESCRIPTION OF THE DRAWINGS

### Description of the Drawings

In order to explain the technical solution in the embodiments of the present application more clearly, reference is now made briefly to the accompanying drawings required for the description of the embodiments. It should be understood that the accompanying drawings in the following description are merely some of the embodiments of the present application, and other drawings may be made to a skilled person in the art based on the accompanying drawings without inventive effort.

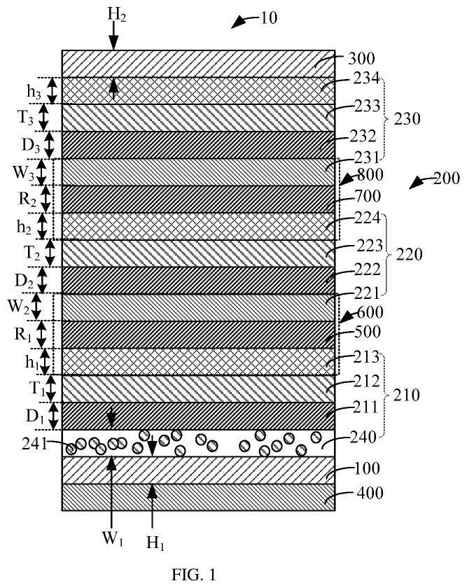

FIG. 1 is a schematic diagram of a first structure of a display panel according to an embodiment of the present application.

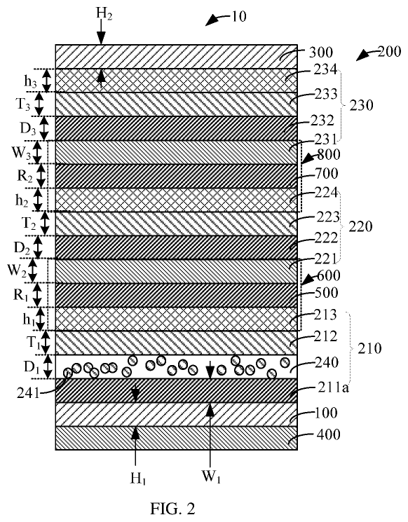

FIG. 2 is a schematic diagram of a second structure of a display panel according to an embodiment of the present application.

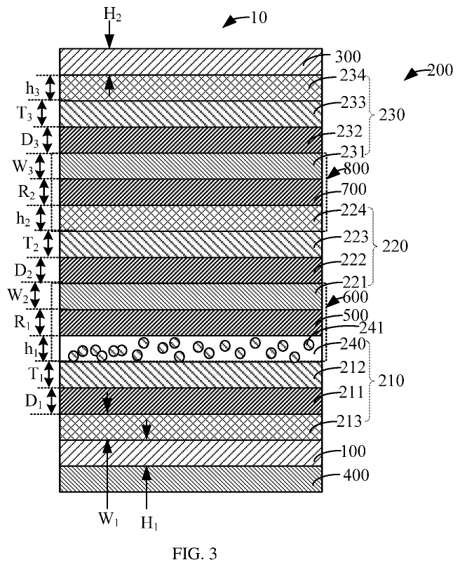

FIG. 3 is a schematic diagram of a third structure of a display panel according to an embodiment of the present application.

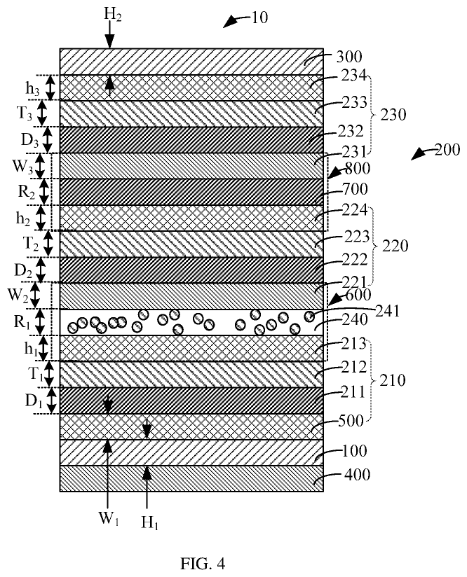

FIG. 4 is a schematic diagram of a fourth structure of a display panel according to an embodiment of the present application.

### DETAILED DESCRIPTION OF THE EMBODIMENTS

In the following, the technical solutions in the embodiments of the present application are clearly and completely described in connection with the accompanying drawings in the embodiments of the present application. It should be understood that the described embodiments are merely a part of the embodiments of the present application, rather than all the embodiments. Based on the embodiments in the present application, all other embodiments obtained by a person skilled in the art without inventive effort are within the scope of the present application. Furthermore, it should be understood that the specific embodiments described herein are for purposes of illustration and explanation only, and are not intended to limit the application. In the present application, without stating to the contrary, the positional terms such as “on” and “below” generally refer to a position located on and below the device in actual use and working state, specifically refer to the direction shown in the accompanying drawings. Moreover, the terms “in” and “out” are for the outline of the device.

The embodiment of the application provides a display panel. Detailed descriptions are given below.

Referring to FIG. 1, FIG. 1 is a schematic diagram of a first structure of a display panel according to an embodiment of the present application. The present application provides a display panel 10. The display panel 10 includes a first electrode layer 100, a light-emitting structure 200, and a second electrode layer 300.

In an embodiment, the display panel 10 further includes a substrate 400. The substrate 400 may be a rigid substrate or a flexible substrate. The flexible substrate may be a polyimide substrate. The rigid substrate may be a glass substrate.

The first electrode layer 100 is disposed on the substrate 400.

In an embodiment, the first electrode layer 100 is an anode or a cathode. In this embodiment, the first electrode layer 100 is an anode.

In an embodiment, the material of the first electrode layer 100 includes one or more of indium tin oxide, indium zinc oxide, zinc aluminum oxide, and indium gallium zinc oxide. In this embodiment, the material of the first electrode layer 100 is indium tin oxide.

In an embodiment, the first electrode layer 100 has a thickness H₁ ranging from 50 nm to 1000 nm. Specifically, the thickness H₁ of the first electrode layer 100 may be 50 nm, 500 nm, 750 nm, 900 nm, 1000 nm, or the like. In the present embodiment, the thickness H₁ of the first electrode layer 100 is 600 nm.

In the present embodiment, by providing the first electrode layer 100 with the thickness H₁ ranging from 50 nm to 1000 nm, the resistance of the first electrode layer 100 is low, and the blocking effect on the current is light, thereby improving the conductive performance of the first electrode layer 100. In a case that the thickness H₁ of the first electrode layer 100 is provided less than 50 nm, the resistance of the first electrode layer 100 is too low, thereby causing a damage to the display panel 10. In a case that the thickness H₁ of the first electrode layer 100 is provided greater than 1000 nm, the resistance of the first electrode layer 100 is excessively high, thereby affecting the conductivity of the first electrode layer 100 and preventing the display panel 10 from displaying normally.

The light-emitting structure 200 is disposed on a side of the first electrode layer 100 away from the substrate 400. The light-emitting structure 200 includes a first light-emitting unit 210, a second light-emitting unit 220, and a third light-emitting unit 230 stacked sequentially. The first light-emitting unit 210, the second light-emitting unit 220, and the third light-emitting unit 230 are independently selected from a red light-emitting unit, a green light-emitting unit, and a blue light-emitting unit, respectively. The first light-emitting unit 210, the second light-emitting unit 220, and the third light-emitting unit 230 emit lights of different colors respectively. The light-emitting structure 200 is provided with a light-converting layer 240. The light-converting layer 240 is disposed on a side of the green light-emitting unit and/or the blue light-emitting unit close to the light-emitting surface of the light-emitting structure. The light-converting layer 240 is doped with red photoluminescence particles 241.

The first light-emitting unit 210 includes a first hole transport layer 211, a first light-emitting layer 212, and a first electron transport layer 213. The light-converting layer 240, the first hole transport layer 211, the first light-emitting layer 212, and the first electron transport layer 213 are stacked sequentially on the first electrode layer 100.

In the present embodiment, the light-converting layer 240 is doped with red photoluminescence particles 241, and the red photoluminescence particles 241 receive lights emitted by the green light-emitting unit and/or the blue light-emitting unit and emit red lights, so that the light-converting layer 240 has a light-converting effect, and the light-emitting structure 200 emits white lights, thereby improving the problem that the color rendering index of the display panel 10 is low, and improving the performance of the display panel 10. The light-converting layer 240 is provided between the first electrode layer 100 and the first hole transport layer 211, so that the light-converting layer 240 can be used as the first hole injection layer of the first light-emitting unit 210, and the conversion effect of the light-converting layer 240, the color rendering index of the display panel 10, and the performance of the display panel 10 are further improved owe to the energy level, mobility, and optical factors of the first electrode layer 100 similar to those of the light-converting layer 240. That is, the first hole injection layer 241 is doped with red photoluminescence particles 241, so that the first hole injection layer has a light-converting effect while functioning as a hole injection layer, and no further design of the light-converting layer 240 is required, thereby reducing the thickness of the display panel 10, and realizing a lightweight design. The light-converting layer 240 is provided on the first electrode layer 100, that is, the red photoluminescence particles 241 are doped in the hole injection layer on the first electrode layer 100 close to the light-emitting side to form the light-converting layer 240, so that the thickness W₁ of the light-converting layer 240 can be selected from a wide range, thereby improving the conversion effect of the light-converting layer 240, and further improving the color rendering index of the display panel.

The color rendering index refers to an effect of a light source to be measured on an appearance of a colored object, compared with a standard light source. That is, a degree of verisimilitude or reality of a color. A higher color rendering index of a light source indicates that the color of the object under the light source is closer to the true color of the object.

In an embodiment, the material of the light-converting layer 240 includes poly(3,4-ethylenedioxythiophene): polystyrene sulfonate, polyaniline, and polythiophene. In this embodiment, the first hole injection layer material is poly(3,4-ethylenedioxythiophene): polystyrene sulfonate.

In an embodiment, each of the red photoluminescence particles 241 is a core-shell structure in which a shell layer covers a core layer. The material of the core layer is selected from CdSe-based quantum dot materials, CdZnSe-based quantum dot materials, InP-based quantum dot materials, and ZnSe-based quantum dot materials, the material of the shell layer is selected from CdS and ZnS. In this embodiment, the material of the core layer is the InP-based quantum dot material, and the material of the shell layer is a combination of CdS and ZnS.

In the present embodiment, the red photoluminescence particle 241 is provided as the core-shell structure in which the shell layer covers the core layer. Because the band gap of the shell layer is greater than the band gap of the core layer, the light-converting layer 240 expands the range of the photon collection spectrum while avoiding the influence of the defect of the core layer on the light emission of the light-converting layer 240. In addition, by adjusting the thickness of the shell layer, the coupling characteristics of the core layer can be prevented from being affected, thereby improving the stability of the display of the display panel 10.

In an embodiment, the material of the core layer is selected from CdSe-based quantum dot materials, CdZnSe-based quantum dot materials, InP-based quantum dot materials, and ZnSe-based quantum dot materials, the material of the shell layer is selected from CdS and ZnS, and the particle diameter of the red photoluminescence particle 241 is provided from 7 nm to 8 nm. In this embodiment, the material of the light-converting layer 240 has a particle diameter of 8 nm, so that the red photoluminescence particles emit red lights.

In an embodiment, the material of the light-converting layer 240 has a photoluminescence wavelength ranging from 600 nm to 630 nm.

In an embodiment, the photoluminescence of the red photoluminescence particle 241 has a full width at half maxima ranging from 40 nm to 90 nm. Specifically, the full width at half maxima of the photoluminescence of the red photoluminescence particle 241 may be 40 nm, 50 nm, 60 nm, 75 nm, 80 nm, 90 nm, or the like.

Full width at half maxima refers to the width of the peak at half the height of the chromatographic peak. This is, a straight line parallel to a bottom of the peak through the midpoints of the peak to intersect both sides of the peak with two points, and full width at half maxima is a distance between the two points.

In an embodiment, a continuous spectrum having a wide full width at half maxima is provided, that is, the full width at half maxima of the photoluminescence of the red photoluminescence particle 241 ranges from 40 nm to 90 nm. Thus, the color rendering index of the white light display panel 10 is increased, thereby improving the performance of the white-light display panel.

The principle of the photoluminescence mechanism is that the quantum dots are irradiated by external lights, so that the quantum dots obtain energy and generate excitations to emit lights.

In an embodiment, the doping concentration of the red photoluminescence particles 241 in the light-converting layer 240 ranges from 10% to 35%. Specifically, the doping concentration of the red photoluminescence particles 241 may be 10%, 12%, 14%, 25%, 30%, 35%, or the like. In this embodiment, the doping concentration of the red photoluminescence particles 241 is 28%.

In this embodiment, the doping concentration of the red photoluminescence particles 241 in the light-converting layer 240 is provided from 10% to 35%, so that the color rendering index of the display panel 10 is increased. In a case that the doping concentration of the red photoluminescence particles 241 in the light-converting layer 240 is provided less than 10%, the light-converting layer 240 requires a sufficient thickness to ensure the color rendering index of the display panel 10, however, the increased thickness of the film layer of the display panel is disadvantageous to the lightweight design. In a case that the doping concentration of the red photoluminescence particles 241 in the light-converting layer 240 is provided greater than 35%, the red photoluminescence particles 241 are needed to generate a phase separation from the organic matters therein, just to ensure the color rendering index of the display panel 10.

Phase separation means that when external conditions such as temperature, pressure, and the like are changed, the multi-component system sometimes separates into several phases having different components and structures. In an embodiment, the light-converting layer 240 has a thickness W₁ ranging from 50 nm to 500 nm. Specifically, the thickness W₁ of the light-converting layer 240 may be 50 nm, 80 nm, 160 nm, 240 nm, 300 nm, 400 nm, 480 nm, 500 nm, or the like. In the present embodiment, the thickness W₁ of the light-converting layer 240 is 200 nm.

In an embodiment, by providing the light-converting layer 240 with the thickness W₁ ranging from 50 nm to 500 nm, the light-converting effect of the light-converting layer 240 is improved. In a case that the thickness W₁ of the light-converting layer 240 is provided less than 50 nm, the light-converting efficiency of the light-converting layer 240 is reduced, and the color rendering index of the display panel 10 is affected. In a case that the thickness W₁ of the light-converting layer 240 is provided greater than 500 nm, the ratio of converting the lights other than the red color to the red color is relatively high, thereby preventing the display panel 10 from emitting white lights.

In an embodiment, the material of the first hole transport layer 211 includes one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, 4,4′-bis(9-carbazol)biphenyl. In this embodiment, the material of the first hole transport layer 211 is 4,4′-bis(9-carbazole)biphenyl.

In an embodiment, the thickness D₁ of the first hole transport layer 211 has a thickness D₁ ranging from 15 nm to 40 nm. Specifically, the thickness D₁ of the first hole transport layer 211 may be 15 nm, 20 nm, 24 nm, 34 nm, 38 nm, 40 nm, or the like. In the present embodiment, the thickness D₁ of the first hole transport layer 211 is 20 nm.

In the present embodiment, the thickness D₁ of the first hole transport layer 211 is provided from 15 nm to 40 nm, to ensure the transport efficiency of holes in the first hole transport layer 211, thereby ensuring the normal display of the display panel 10.

The first light-emitting layer 212 is disposed on a side of the first hole transport layer 211 away from the first electrode layer 100.

In an embodiment, the first light-emitting layer 212 includes one of a red light-emitting layer, a green light-emitting layer, and a blue light-emitting layer. In this embodiment, the first light-emitting layer 212 is a blue light-emitting layer, that is, the first light-emitting unit 210 is a blue light-emitting unit.

In an embodiment, the material of the first light-emitting layer 212 is a core-shell structure in which a shell layer covers a core layer. The band gap of the shell layer is larger than the band gap of the core layer.

In an embodiment, the material of the core layer includes at least one of CdSe, CdZnSe, InP, and ZnSe. The material of the shell layer includes one or a combination of CdS and ZnS. In this embodiment, the material of the core layer is ZnSe, and the material of the shell layer is CdS.

In an embodiment, the first light-emitting layer 212 material has a particle diameter ranging from 1 nm to 2 nm. In this embodiment, the first light-emitting layer 212 material has a particle diameter of 2 nm.

In the present application, the material of the core layer is a combination of CdSe, CdZnSe, InP, and ZnSe, the material of the shell layer is a combination of CdS and ZnS, and the particle diameter of the first light-emitting layer 212 is provided from 1 nm to 2 nm. As such, the first light-emitting layer 212 emits blue lights.

In an embodiment, the material of the first light-emitting layer 212 has a photoluminescence wavelength ranging from 465 nm to 480 nm.

In an embodiment, the first light-emitting layer 212 has a thickness T₁ ranging from 10 nm to 40 nm. Specifically, the thickness T₁ of the first light-emitting layer 212 may be 10 nm, 12 nm, 15 nm, 20 nm, 24 nm, 34 nm, 38 nm, 40 nm, or the like. In this embodiment, the thickness T₁ of the first light-emitting layer 212 is 20 nm.

In the present embodiment, the thickness T₁ of the first light-emitting layer 212 is provided from 10 nm to 40 nm, so that the first light-emitting layer 212 can emit lights normally, and the display panel 10 can be displayed normally.

In an embodiment, the material of the first electron transport layer 213 is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1. In the present embodiment, the material of the first electron transport layer 213 is Zn_{0.95}Mg_{0.05}O.

In an embodiment, the first electron transport layer 213 has a thickness h₁ ranging from 20 nm to 60 nm. Specifically, the thickness h₁ of the first electron transport layer 213 may be 20 nm, 24 nm, 34 nm, 38 nm, 40 nm, 50 nm, 54 nm, 60 nm, or the like. In the present embodiment, the thickness h₁ of the first electron transport layer 213 is 30 nm.

In the present embodiment, by providing the first electron transport layer 213 the thickness h₁ from 20 nm to 60 nm, the electron transport performance of the first electron transport layer 213 is ensured, and the normal display of the display panel 10 is further ensured.

In an embodiment, the display panel 10 includes a first transparent conductive layer 500. The first transparent conductive layer 500 is disposed on a side of the first electron transport layer 213 away from the first electrode layer 100.

In an embodiment, the material of the first transparent conductive layer 500 is selected from indium tin oxide, indium zinc oxide, zinc aluminum oxide, indium gallium zinc oxide, zinc oxide, and zinc manganese oxide. In this embodiment, the material of the first transparent conductive layer 500 is indium zinc oxide.

In an embodiment, the first transparent conductive layer 500 has a thickness R₁ ranging from 50 nm to 1000 nm. Specifically, the thickness R₁ of the first transparent conductive layer 500 may be 50 nm, 500 nm, 750 nm, 900 nm, 1000 nm, or the like. In the present embodiment, the thickness R₁ of the first transparent conductive layer 500 is 100 nm.

In the present embodiment, the thickness R₁ of the first transparent conductive layer 500 is provided from 50 nm to 1000 nm, to avoid the subsequent influence of the second hole injection layer 221 on the first electron transport layer 213, thereby ensuring the injection and the transmission of electrons of the first electron transport layer 213, thereby ensuring the normal display of the display panel 10. In a case that the thickness R₁ of the first transparent conductive layer 500 is provided less than 50 nm, the second hole injection layer 221 may affect the electron injection and transmission efficiency of the first electron transport layer 213, which is disadvantageous over the normal display of the display panel 10. In a case that the thickness R₁ of the first transparent conductive layer 500 is provided to 1000 nm, the resistance of the first transparent conductive layer 500 is increased, and the conductivity of the first transparent conductive layer 500 is reduced, thereby affecting the display performance of the display panel 10.

The second light-emitting unit 220 includes a second hole injection layer 221, a second hole transport layer 222, a second light-emitting layer 223, and a second electron transport layer 224 sequentially stacked on the first transparent conductive layer 500.

In an embodiment, the material of the second hole injection layer 221 is selected from poly(3,4-ethylenedioxythiophene): polystyrene sulfonate, polyaniline, and polythiophene. In this example, the material of the second hole injection layer 221 is poly(3,4-ethylenedioxythiophene): polystyrene sulfonate.

In an embodiment, the second hole injection layer 221 has a thickness W₂ ranging from 15 nm to 50 nm. Specifically, the thickness W₂ of the second hole injection layer 221 may be 15 nm, 20 nm, 24 nm, 34 nm, 38 nm, 40 nm, 48 nm, 50 nm, or the like. In this embodiment, the thickness W₂ of the second hole injection layer 221 is 25 nm.

In the present embodiment, the thickness W₂ of the second hole injection layer 221 is provided from 15 nm to 50 nm to ensure the injection efficiency of holes in the second hole injection layer 221, thereby ensuring the normal display of the display panel 10.

The first electron transport layer 213, the first transparent conductive layer 500, and the second hole injection layer 221 define a first charge layer 600 of the light-emitting structure 200. The first charge layer 600 functions to provide holes and electrons required for the light-emitting structure 200.

In the present embodiment, the first charge layer 600 is defined by the first electron transport layer 213, the first transparent conductive layer 500, and the second hole injection layer 221. Since the first transparent conductive layer 500 is in form of a N-type semiconductor, and the second hole injection layer 221 is in form of a P-type semiconductor, the first transparent conductive layer 500 and the second hole injection layer 251 together define a P-N junction. With the conduction band of the first transparent conductive layer 500 equal to or less than the highest occupied molecular orbital (HOMO) of the second hole injection layer 221, when an external electric field is applied, electrons and holes are generated at the P-N junction, electrons are injected into the light-emitting unit through the first transparent conductive layer 500, and the holes are injected into another light-emitting unit. That is, the first charge layer 600 can generate enough electrons and holes, thereby avoiding a problem of energy transfer caused by the stacked arrangement of the light-emitting layers of the display panel 10, and further avoiding a problem of uneven display of the display panel 10. Further, the stability of the white display panel 10 is improved.

In the present embodiment, since the light-converting layer 240 is doped with the red photoluminescence particles 241, the light-converting layer 240 has a light-converting effect while functioning as a hole injection layer of the first light-emitting unit 210, thereby improving the color rendering index of the white-light display panel 10, and further improving the performance of the white-light display panel.

In an embodiment, the material of the second hole transport layer 222 includes one or more of poly(9,9-dioctylfluorene-co-N-(4-butylphenyl)diphenylamine), poly(N,N′-bis(4-butylphenyl)-N,N″-bis(phenyl)-benzidine), polyvinylcarbazole, 4,4′,4″-tris(carbazol-9-yl)triphenylamine, and 4,4′-bis(9-carbazol)biphenyl. In this embodiment, the material of the second hole transport layer 222 is polyvinylcarbazole.

In an embodiment, the second hole transport layer 222 has a thickness D₂ ranging from 15 nm to 40 nm. Specifically, the thickness D₂ of the second hole transport layer 222 may be 15 nm, 20 nm, 24 nm, 34 nm, 38 nm, 40 nm, or the like. In this embodiment, the thickness D₂ of the second hole transport layer 222 is 25 nm.

In the present embodiment, the thickness D₂ of the second hole transport layer 222 is provided from 15 nm to 40 nm to ensure the transport efficiency of holes in the second hole transport layer 222, thereby ensuring the normal display of the display panel 10.

In an embodiment, the second light-emitting layer 223 includes one of a red light-emitting layer, a green light-emitting layer, and a blue light-emitting layer. In this embodiment, the second light-emitting layer 223 is a green light-emitting layer, that is, the second light-emitting unit 220 is a green light-emitting unit.

In an embodiment, the second light-emitting layer 223 is a core-shell structure in which a shell layer covers a core layer. The material of the core layer includes one of CdSe, CdZnSe, InP, and ZnSe, and the material of the shell layer includes one or a combination of CdS and ZnS. In this embodiment, the material of the core layer is CdZnSe, and the material of the shell layer is CdS.

In an embodiment, the second light-emitting layer 223 material has a particle diameter ranging from 3 nm to 6 nm. In this embodiment, the second light-emitting layer 223 material has a particle diameter of 5 nm.

In the present embodiment, the material of the core layer is a combination of CdSe, CdZnSe, InP, and ZnSe, the material of the shell layer is a combination of CdS and ZnS, and the particle diameter of the second light-emitting layer 223 ranges from 3 nm to 6 nm. As such, the second light-emitting layer 223 emits green lights.

In an embodiment, the material of the second light-emitting layer 223 material has a photoluminescence wavelength ranging from 535 nm to 555 nm.

In an embodiment, the second light-emitting layer 223 has a thickness T₂ ranging from 10 nm to 40 nm. Specifically, the thickness T₂ of the second light-emitting layer 223 may be 10 nm, 12 nm, 15 nm, 20 nm, 24 nm, 34 nm, 38 nm, 40 nm, or the like. In this embodiment, the thickness T₂ of the second light-emitting layer 223 is 15 nm.

In the present embodiment, the thickness T₂ of the second light-emitting layer 223 is provided from 10 nm to 40 nm, so that the second light-emitting layer 223 can normally emit lights, and further the display panel 10 can normally display.

In an embodiment, the material of the second electron transport layer 224 is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1.

In an embodiment, the material of the second electron transport layer 224 may be Zn_{0.98}Al_{0.02}O, Zn_{0.9}Mg_{0.05}Li_{0.05}O, Zn_{0.9}Mg_{0.1}O, Zn_{0.88}Mg_{0.12}O, or the like. In this embodiment, the material of the second electron transport layer 224 is Zn_{0.95}Mg_{0.05}O.

In an embodiment, the second electron transport layer 224 has a thickness h₂ ranging from 20 nm to 60 nm. Specifically, the thickness h₂ of the second electron transport layer 224 may be 20 nm, 24 nm, 34 nm, 38 nm, 40 nm, 50 nm, 54 nm, 60 nm, or the like. In this embodiment, the thickness h₂ of the second electron transport layer 224 is 38 nm.

In the present embodiment, the thickness h₂ of the second electron transport layer 224 is provided from 20 nm to 60 nm, to ensure the electron transport performance of the second electron transport layer 224, and further ensure the normal display of the display panel 10.

In an embodiment, the display panel 10 further includes a second transparent conductive layer 700. The second transparent conductive layer 700 is disposed on the second electron transport layer 224.

In an embodiment, the material of the second transparent conductive layer 700 is selected from indium tin oxide, indium zinc oxide, zinc aluminum oxide, indium gallium zinc oxide, zinc oxide, and zinc manganese oxide. In this embodiment, the material of the second transparent conductive layer 700 is indium zinc oxide.

In an embodiment, the second transparent conductive layer 700 has a thickness R₂ ranging from 50 nm to 1000 nm. Specifically, the thickness R₂ of the second transparent conductive layer 700 may be 50 nm, 500 nm, 750 nm, 900 nm, 1000 nm, or the like. The thickness R₂ of the second transparent conductive layer 700 is 500 nm.

In the present embodiment, the thickness R₂ of the second transparent conductive layer 700 is provided from 50 nm to 1000 nm, so as to avoid the subsequent influence of the third hole injection layer 231 on the second electron transport layer 224, thereby ensuring the injection and the transmission of electrons of the second electron transport layer 224, thereby ensuring the normal display of the display panel 10. In a case that the thickness R₂ of the second transparent conductive layer 700 is provided less than 50 nm, the third hole injection layer 231 may affect the electron injection and transmission efficiency of the second electron transport layer 224, which is disadvantageous over the normal display of the display panel 10. In a case that the thickness R₂ of the second transparent conductive layer 700 is provided to 1000 nm, the resistance of the second transparent conductive layer 700 is increased, and the conductivity of the second transparent conductive layer 700 is reduced, thereby affecting the display performance of the display panel 10.

The third light-emitting unit 230 includes a third hole injection layer 231, a third hole transport layer 232, a third light-emitting layer 233, and a third electron transport layer 234 sequentially stacked on the second transparent conductive layer 700.

In an embodiment, the material of the third hole injection layer 231 is selected from poly(3,4-ethylenedioxythiophene): polystyrene sulfonate, polyaniline, and polythiophene. In this embodiment, the material of the third hole injection layer 231 is polythiophene.

In an embodiment, the third hole injection layer 231 has a thickness W₃ ranging from 15 nm to 50 nm. Specifically, the thickness W₃ of the third hole injection layer 231 may be 15 nm, 20 nm, 24 nm, 34 nm, 38 nm, 40 nm, 48 nm, 50 nm, or the like. In this embodiment, the thickness W₃ of the third hole injection layer 231 is 39 nm.

In the present embodiment, the thickness W₃ of the third hole injection layer 231 is provided from 15 nm to 50 nm, to ensure the injection efficiency of the holes in the third hole injection layer 231, thereby ensuring normal display of the display panel 10.

The second electron transport layer 224, the second transparent conductive layer 700, and the third hole injection layer 231 define a second charge layer 800 of the light-emitting structure 200. The second charge layer 800 functions to provide holes and electrons required for the light-emitting structure 200.

In the present embodiment, the second charge layer 800 is defined by the second electron transport layer 224, the second transparent conductive layer 700, and the third hole injection layer 231. Since the second transparent conductive layer 700 is in form of a N-type semiconductor, and the third hole injection layer 231 is in form of a P-type semiconductor, the second transparent conductive layer 700 and the third hole injection layer 231 together define a P-N junction. With the conduction band of the second transparent conductive layer 700 equal to or less than the highest occupied molecular orbital (HOMO) of the third hole injection layer 231, when an external electric field is applied, electrons and holes are generated at the P-N junction, electrons are injected into the light-emitting unit through the second transparent conductive layer 700, and the holes are injected into another light-emitting unit. That is, the second charge layer 800 can generate enough electrons and holes, thereby avoiding a problem of energy transfer caused by the stacked arrangement of the light-emitting layers of the display panel 10, and further avoiding a problem of uneven display of the display panel 10. Further, the stability of the display panel 10 is improved.

In an embodiment, the material of the third hole transport layer 232 includes one or more of poly(9,9-dioctylfluorene-co-N-(4-butylphenyl)diphenylamine), poly(N,N′-bis(4-butylphenyl)-N,N″-bis(phenyl)-benzidine), polyvinylcarbazole, 4,4′,4″-tris(carbazol-9-yl)triphenylamine, and 4,4′-bis(9-carbazol)biphenyl. In this embodiment, the third hole transport layer 232 material is poly(N,N′-bis(4-butylphenyl)-N,N″-bis(phenyl)-benzidine).

In an embodiment, the third hole transport layer 232 has a thickness D₃ ranging from 15 nm to 40 nm. Specifically, the thickness D₃ of the third hole transport layer 232 may be 15 nm, 20 nm, 24 nm, 34 nm, 38 nm, 40 nm, or the like. In this embodiment, the thickness D₃ of the third hole transport layer 232 is 18 nm.

In the present embodiment, the thickness D₃ of the third hole transport layer 232 is provided from 15 nm to 40 nm to ensure the transport efficiency of the holes in the third hole transport layer 232, thereby ensuring the normal display of the display panel 10.

In an embodiment, the third light-emitting layer 233 includes one of a red light-emitting layer, a green light-emitting layer, and a blue light-emitting layer. In this embodiment, the third light-emitting layer 233 is a red light-emitting layer, that is, the third light-emitting unit 230 is a red light-emitting unit.

In an embodiment, the material of the third light-emitting layer 233 is a core-shell structure in which a shell layer covers a core layer. The material of the core layer includes one of CdSe, CdZnSe, InP, and ZnSe. The material of the shell layer includes one or a combination of CdS and ZnS. In this embodiment, the material of the core layer is ZnSe, and the material of the shell layer is a combination of CdS and ZnS.

In an embodiment, the material of the third light-emitting layer 233 has a particle diameter ranging from 7 nm to 8 nm. In this embodiment, the third light-emitting layer 233 material has a particle diameter of 8 nm.

In this embodiment, the material of the core layer is a combination of CdSe, CdZnSe, InP, and ZnSe, the material of the shell layer is a combination of CdS and ZnS, and the particle diameter of the third light-emitting layer 233 ranges from 7 nm to 8 nm. As such, the third light-emitting layer 233 emits red lights.

In an embodiment, the material of the third light-emitting layer 233 has a photoluminescence wavelength ranging from 615 nm to 625 nm.

In an embodiment, the third light-emitting layer 233 has a thickness T₃ ranging from 10 nm to 40 nm. Specifically, the thickness T₃ of the third light-emitting layer 233 may be 10 nm, 12 nm, 15 nm, 20 nm, 24 nm, 34 nm, 38 nm, 40 nm, or the like. In this embodiment, the thickness T₃ of the third light-emitting layer 233 is 22 nm.

In the present embodiment, the thickness T₃ of the third light-emitting layer 233 is provided from 10 nm to 40 nm, so that the third light-emitting layer 233 can emit lights normally, and the display panel 10 can be displayed normally.

In an embodiment, the material of the third electron transport layer 234 is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1. In this embodiment, the material of the third electron transport layer 234 is Zn_{0.85}Mg_{0.05}Li_{0.1}O.

In an embodiment, the third electron transport layer 234 has a thickness h₃ ranging from 20 nm to 60 nm. Specifically, the thickness h₃ of the third electron transport layer 234 may be 20 nm, 24 nm, 34 nm, 38 nm, 40 nm, 50 nm, 54 nm, 60 nm, or the like. In this embodiment, the thickness h₃ of the third electron transport layer 234 is 54 nm.

In an embodiment, the display panel 10 further includes a second electrode layer 300. The second electrode layer 300 is disposed on a side of the third electron transport layer 234 away from the first electrode layer 100.

In an embodiment, the material of the second electrode layer 300 includes gold, silver, aluminum, alloys thereof, and the like. In this embodiment, the material of the second electrode layer 300 is gold.

In an embodiment, the second electrode layer 300 has a thickness H₂ ranging from 80 nm to 500 nm. Specifically, the thickness H₂ of the second electrode layer 300 may be 80 nm, 120 nm, 340 nm, 480 nm, 500 nm, or the like. In this embodiment, the thickness H₂ of the second electrode layer 300 may be 100 nm. In this embodiment, the thickness H₂ of the second electrode layer 300 may be 490 nm. The second electrode layer 300 is an anode or a cathode, and in this embodiment, the second electrode layer 300 is a cathode.

The present application provides a display panel, wherein a light-converting layer doped with red photoluminescence particles is provided between a first electrode layer and a first hole transport layer. That is, a first hole injection layer doped with red photoluminescence particles is provided between the first electrode layer and the first hole transport layer. As such, the first hole injection layer has a light-converting effect without affecting the performance of the first hole injection layer, thereby improving the color rendering index of the white-light display panel, and further improving the performance of the white-light display panel.

Referring to FIG. 2, FIG. 2 is a schematic diagram of a second structure of a display panel according to an embodiment of the present application. It should be noted that the second structure may differ from the first structure in the followings.

The light-converting layer 240 is disposed between the first hole injection layer 211a and the first light-emitting layer 212.

In an embodiment, the material of the light-converting layer 240 is selected from one or more of poly(9,9-dioctylfluorene-co-N-(4-butylphenyl)diphenylamine), poly(N,N′-bis(4-butylphenyl)-N,N′bis(phenyl)benzidine), polyvinylcarbazole, 4,4′,4″-tris(carbazol-9-yl)triphenylamine, 4,4′-bis(9-carbazol)biphenyl. In this embodiment, the material of the light-converting layer 240 is 4,4′-bis(9-carbazole)biphenyl.

In the present embodiment, the light-converting layer 240 is disposed between the first hole injection layer 211a and the first light-emitting layer 212, as such, the light-converting layer 240 can be used as the first hole transport layer of the first light-emitting unit 210. The red photoluminescence particles are doped in the first hole transport layer, as such, the first hole transport layer has a hole transport layer performance while having a light conversion effect. Thus, a problem that the color rendering index of the display panel 10 is low due to red light being absorbed by other lights is avoided, thereby improving the color rendering index of the display panel 10, and improving the display performance of the display panel 10.

Referring to FIG. 3, FIG. 3 is a schematic diagram of a third structure of a display panel according to an embodiment of the present application. It should be noted that the third structure may differ from the first structure in the followings.

The light-converting layer 240 is disposed between the first light-emitting layer 212 and the first transparent conductive layer 500.

In an embodiment, the material of the light-converting layer is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1. In the present embodiment, the light-converting layer material is Zn_{0.92}Mg_{0.08}O.

In the present embodiment, the light-converting layer 240 is disposed between the first light-emitting layer 212 and the first transparent conductive layer 500, as such, the light-converting layer 240 can be used as the first electron transport layer of the first light-emitting unit 210. The red photoluminescence particles are doped in the first electron transport layer instead of being doped in the first hole injection layer 211a, so that the first electron transport layer has the performance of the electron transport layer while having a light-converting effect. Thus, a problem that the color rendering index of the display panel 10 is low due to red light being absorbed by other lights is avoided, thereby improving the color rendering index of the display panel 10, and improving the display performance of the display panel 10.

Referring to FIG. 4, FIG. 4 is a schematic diagram of a fourth structure of a display panel according to an embodiment of the present application. It should be noted that the fourth structure may differ from the first structure in the followings.

The light-converting layer 240 is provided between the first electron transport layer 213 and the second hole injection layer 221, or between the second electron transport layer 224 and the third hole injection layer 231.

In an embodiment, the material of the light-converting layer 240 is selected from indium tin oxide, indium zinc oxide, zinc aluminum oxide, indium gallium zinc oxide, zinc oxide, and zinc manganese oxide.

In the present embodiment, the light-converting layer 240 is disposed between the first electron transport layer 213 and the second hole injection layer 221, or between the second electron transport layer 224 and the third hole injection layer 231, as such, the light-converting layer 240 can be used as the first transparent conductive layer or the second transparent conductive layer of the light-emitting structure 200. The red photoluminescence particles are doped in the first transparent conductive layer or the second transparent conductive layer, as such, the first transparent conductive layer or the second transparent conductive layer has the performance of the transparent conductive layer while having the light-converting effect. Thus, a problem that the color rendering index of the display panel 10 is low due to red light being absorbed by other lights is avoided, thereby improving the color rendering index of the display panel 10, and improving the display performance of the display panel 10.

In an embodiment, the red photoluminescence particles 241 may be doped with the film layers in the second light-emitting unit 220 and the third light-emitting unit 230 to form the light-converting layer 240. For example, the red photoluminescence particles 241 may be doped with the second hole injection layer 221, the second electron transport layer 224, the third hole injection layer 231, or the like. Meanwhile, the light-converting layer 240 is disposed on a side of the green light-emitting layer and/or the blue light-emitting layer close to the light-emitting surface of the light-emitting structure 200.

In an embodiment, the film layers other than the first light-emitting layer 212, the second light-emitting layer 223, and the third light-emitting layer 233 in the first light-emitting unit 210, the second light-emitting unit 220, and the third light-emitting unit 230 are doped with a small amount of red photoluminescence particles 241. The light-converting layer 240 is provided on a side of the green light-emitting layer and/or the blue light-emitting layer close to the light-emitting surface of the light-emitting structure 200.

The display panel 10 of the present application may be a white quantum dot light-emitting diode display panel or a white organic light-emitting diode display panel.

The display panel 10 of the present application may be a photoluminescence display panel or an electroluminescent display panel.

An embodiment of the present application discloses a display panel. The display panel includes a first electrode layer, a light-emitting structure, and a second electrode layer. The light-emitting structure is disposed on the first electrode, and includes a first light-emitting unit, a second light-emitting unit, and a third light-emitting unit stacked sequentially. The first light-emitting unit, the second light-emitting unit, and the third light-emitting unit are independently selected from a red light-emitting unit, a green light-emitting unit, and a blue light-emitting unit, respectively. The first light-emitting unit, the second light-emitting unit, and the third light-emitting unit emit lights of different colors respectively. The light-emitting structure is provided with a light-converting layer, the light-converting layer is doped with red light-emitting particles, and the light-converting layer is provided on a side of the green light-emitting unit and/or the blue light-emitting unit close to a light-emitting surface of the light-emitting structure. The second electrode layer is disposed on the first electrode layer of the light-emitting structure. In the present application, by providing the light-converting layer in the light-emitting structure, the color rendering index of the white-light display panel is improved, and the performance of the white-light display panel is further improved.

A display panel provided by the present application is described in details, and the principles and embodiments of the present application are described with reference to specific examples. The description of the above examples is merely provided to help understand the method and the core idea of the present application. At the same time, variations to the detailed embodiments and the scope of application will occur to those skilled in the art in accordance with the teachings of the present application. In view of the foregoing, the present description should not be construed as limiting the application.

1. A display panel, comprising:
a first electrode layer;
a light-emitting structure disposed on the first electrode layer, wherein the light-emitting structure comprises a first light-emitting unit, a second light-emitting unit, and a third light-emitting unit; the first light-emitting unit, the second light-emitting unit, and the third light-emitting unit are independently selected from a red light-emitting unit, a green light-emitting unit, and a blue light-emitting unit, respectively; and the first light-emitting unit, the second light-emitting unit, and the third light-emitting unit emit lights of different colors respectively; wherein the light-emitting structure is provided with a light-converting layer, the light-converting layer is disposed on a side of the green light-emitting unit and/or the blue light-emitting unit close to a light-emitting surface of the light-emitting structure, and the light-converting layer is doped with red photoluminescence particles; and
a second electrode layer disposed on a side of the light-emitting structure away from the first electrode layer.

2. The display panel of claim 1, wherein the red photoluminescence particles are configured to receive lights emitted by the green light-emitting unit and/or the blue light-emitting unit and to emit red light, and the light-emitting structure emits white lights.

3. The display panel of claim 1, wherein the red photoluminescence particles are selected from of CdSe-based quantum dot materials, CdZnSe-based quantum dot materials, InP-based quantum dot materials, and ZnSe-based quantum dot materials.

4. The display panel of claim 1, wherein a doping concentration of the red photoluminescence particles in the light-converting layer ranges from 10% to 35%.

5. The display panel of claim 1, wherein the first light-emitting unit comprises a first light-emitting layer, a first electron transport layer, and a first hole transport layer; and the light-converting layer, the first hole transport layer, the first light-emitting layer, and the first electron transport layer are stacked sequentially on the first electrode layer.

6. The display panel of claim 5, wherein a material of the light-converting layer is selected from poly(3,4-ethylenedioxythiophene): polystyrene sulfonate, polyaniline, and polythiophene.

7. The display panel of claim 1, wherein the first light-emitting unit comprises a first hole injection layer, a first light-emitting layer, and a first electron transport layer; and the first hole injection layer, the light-converting layer, the first light-emitting layer, and the first electron transport layer are stacked sequentially on the first electrode layer.

8. The display panel of claim 7, wherein a material of the light-converting layer is selected from poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, and 4,4′-bis(9-carbazol)biphenyl.

9. The display panel of claim 1, wherein the first light-emitting unit comprises a first hole injection layer, a first hole transport layer, and a first light-emitting layer; and the first hole injection layer, the first hole transport layer, the first light-emitting layer, and the light-converting layer are stacked sequentially on the first electrode layer.

10. The display panel of claim 9, wherein a material of the light-converting layer is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1.

11. The display panel of claim 1, wherein the light-converting layer is disposed between the first light-emitting unit and the second light-emitting unit, or between the second light-emitting unit and the third light-emitting unit.

12. The display panel of claim 11, wherein a material of the light-converting layer is selected from indium tin oxide, indium zinc oxide, zinc aluminum oxide, indium gallium zinc oxide, zinc oxide, and zinc manganese oxide.

13. The display panel of claim 12, wherein the second light-emitting unit comprises a second hole injection layer, a second hole transport layer, a second light-emitting layer, and a second electron transport layer stacked sequentially; wherein the third light-emitting unit comprises a third hole injection layer, a third hole transport layer, a third light-emitting layer, and a third electron transport layer stacked sequentially; wherein the display panel further comprises a first transparent conductive layer disposed between the first light-emitting unit and the second light-emitting unit and/or a second transparent conductive layer disposed between the second light-emitting unit and the third light-emitting unit.

14. The display panel of claim 13, wherein a material of each of the first light-emitting layer, the second light-emitting layer, and the third light-emitting layer is a core-shell structure, and a shell layer of the core-shell structure covers a core layer of the core-shell structure; wherein a material of the core layer comprises at least one of CdSe, CdZnSe, InP, and ZnSe, and a material of the shell layer comprises one or a combination of CdS and ZnS.

15. The display panel of claim 13, wherein the first transparent conductive layer is selected from indium tin oxide, indium zinc oxide, zinc aluminum oxide, indium gallium zinc oxide, zinc oxide, and zinc manganese oxide; and
the second transparent conductive layer is selected from indium tin oxide, indium zinc oxide, zinc aluminum oxide, indium gallium zinc oxide, zinc oxide, and zinc manganese oxide.

16. The display panel of claim 13, wherein the first transparent conductive layer and the second transparent electrode layer each have a thickness ranging from 50 nm to 1000 nm.

17. The display panel of claim 13, wherein a material of each of the second electron transport layer and the third electron transport layer is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, and n1+n2+n3=1.

18. The display panel of claim 13, wherein a material of the second hole transport layer comprises one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, and 4,4′-bis(9-carbazol)biphenyl; and
a material of the third hole transport layer includes one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, and 4,4′-bis(9-carbazol)biphenyl.

19. The display panel of claim 13, wherein materials of the second hole injection layer and the third hole injection layer are independently selected from poly(3,4-ethylenedioxythiophene):polystyrene sulfonate, poly aniline, and polythiophene.

20. The display panel of claim 13, wherein the second hole injection layer and the third hole injection layer each have a thickness ranging from 15 nm to 50 nm.
